(19) United States
(12) Patent Application Publication
(10) Pub. No.: US 2025/0232427 A1
(43) Pub. Date: Jul. 17, 2025

(54) ANALYSIS METHOD AND EVALUATION METHOD

(71) Applicant: SCREEN Holdings Co., Ltd., Kyoto (JP)

(72) Inventors: Satoshi OKAMOTO, Kyoto-shi (JP); Tomoyasu FURUTA, Kyoto-shi (JP)

(21) Appl. No.: 19/016,440

(22) Filed: Jan. 10, 2025

(30) Foreign Application Priority Data
Jan. 12, 2024 (JP) 2024-003273

(51) Int. Cl. G06T 7/00; G01N 21/85; H01L 21/02; H01L 21/66

(52) U.S. Cl. CPC G06T 7/0004; G01N 21/85; G06T 2207/10016; G06T 2207/30148; H01L 21/02057; H01L 22/10

(57) ABSTRACT

An analysis method for analyzing a state of a liquid membrane, on a substrate, of a liquid supplied to the substrate that is rotating in a substrate processing apparatus includes: a process (S303) of calculating a first statistic from luminance values of individual pixels in a predetermined region from a video image obtained by imaging a surface of the substrate; a process (S304) of calculating at least one second statistic that is a statistic of time-series data of the first statistics; and a process (S305) of analyzing a state of the liquid membrane on the substrate based on at least one of the first statistic or the second statistic. The first statistic includes a luminance average value obtained by averaging the luminance values and a dissimilarity average value obtained by averaging dissimilarities of the luminance values. The second statistic includes at least one of a luminance statistic which is a statistic of the luminance average value or a dissimilarity statistic which is a statistic of the dissimilarity average value. As a result, a state of the liquid membrane on the substrate can be quantitatively analyzed.

### RELATED APPLICATIONS

This application claims the benefit of Japanese Application No. 2024-003273, filed on Jan. 12, 2024, the disclosure of which is incorporated by reference herein.

### BACKGROUND OF THE INVENTION

### Field of the Invention

The present invention relates to an analysis method for analyzing a state of a liquid membrane, on a substrate, of a liquid supplied to the substrate that is rotating in a substrate processing apparatus.

### Description of the Background Art

A cleaning process which accounts for 30% to 40% of a process of manufacturing a semiconductor has a large influence on quality and a yield of the semiconductor. Along with ultrafine miniaturization of semiconductor devices, it is increasingly required to cope with fine foreign matters and grime in the cleaning process. In a semiconductor cleaning apparatus, a slight difference in an operation may cause a decrease in output quality. Therefore, in inspection of the apparatus, control observation during the operation as a factor of the decrease in output quality is also required in addition to confirmation of the output quality of the apparatus.

In a spin processor most commonly used as a sheet-fed cleaning apparatus for a semiconductor substrate, cleaning is performed by supplying a chemical liquid or pure water to a rotating wafer. Since it is considered that a state of a liquid membrane on the substrate in the cleaning process affects a process result, it is required to observe, analyze, and evaluate the state of the liquid membrane.

A conventional approach of installing a video camera in an apparatus and inspecting an operation of the apparatus is described in, for example, JP 2023-96643 A. In JP 2023-96643 A, a behavior of a substrate rotating at a high speed is observed using an event-based camera. However, an index for quantifying and evaluating a state of a liquid membrane is not mentioned.

### SUMMARY OF THE INVENTION

The present invention has been made in view of such circumstances, and an object of the present invention is to provide a technique for quantitatively analyzing a state of a liquid membrane on a substrate in a substrate processing apparatus.

In order to solve the above problem, a first aspect of the present application is an analysis method for analyzing a state of a liquid membrane, on a substrate, of a liquid supplied to the substrate that is rotating in a substrate processing apparatus, the analysis method including: a) acquiring luminance values of individual pixels in a region that is predetermined, from a video image obtained by imaging a surface of the substrate, and calculating a first statistic from the luminance values; b) calculating a second statistic that is a statistic of time-series data of the first statistic; and c) analyzing a state of the liquid membrane on the substrate based on at least one of the first statistic or the second statistic, in which the first statistic includes a luminance average value obtained by averaging the luminance values of the region and a dissimilarity average value obtained by averaging dissimilarities of the luminance values of the region, and the second statistic includes at least one of a luminance statistic that is a statistic of time-series data of the luminance average value or a dissimilarity statistic that is a statistic of time-series data of the dissimilarity average value.

A second aspect of the present application is the analysis method according to the first aspect, in which the luminance statistic includes a luminance standard deviation value that is a standard deviation of the luminance average values for each period of a predetermined length.

A third aspect of the present application is the analysis method according to the first aspect, in which the dissimilarity statistic includes a dissimilarity standard deviation that is a standard deviation of the dissimilarity average values for each period of a predetermined length.

A fourth aspect of the present application is the analysis method according to the first aspect, in which the dissimilarity statistic includes a dissimilarity moving average differential value that is a first order differential of the dissimilarity moving average.

A fifth aspect of the present application is the analysis method according to the first aspect, in which the dissimilarity statistic includes a dissimilarity moving average differential value that is a first order differential of the dissimilarity moving average, in the process a), the video image is obtained by capturing an image of a first state, a transition period of transition from the first state to a second state, and the second state, and, in the process of c), a switching completion time at which the liquid membrane on the substrate has become stable in the second state is analyzed based on the dissimilarity moving average differential value.

A sixth aspect of the present application is the analysis method according to the fifth aspect, in which the dissimilarity statistic includes: a dissimilarity moving average differential value that is a first order differential of the dissimilarity moving average; and a moving average of the dissimilarity moving average differential value, in the process of c), a time at which a moving average of the dissimilarity moving average differential value falls below a first threshold that is a predetermined negative value is set as a start time of the transition period, and a time at which a moving average of the dissimilarity moving average differential value exceeds a second threshold after showing a negative peak a predetermined number of times is set as the switching completion time.

A seventh aspect of the present application is an evaluation method for analyzing and evaluating a state of a liquid membrane, on a substrate, of a liquid supplied to the substrate that is rotating in a substrate processing apparatus, the evaluation method including: a process of p) acquiring luminance values of individual pixels from a predetermined region of a video image obtained by imaging a surface of each of a plurality of the substrates when an identical process is performed on the substrates, and calculating a first statistic from the luminance values; a process of q) calculating a second statistic that is a statistic of time-series data of the first statistic; and a process of r) analyzing and evaluating a state of the liquid membrane on the substrate based on at least one of the first statistic or the second statistic, in which the first statistic includes a luminance average value obtained by averaging the luminance values of the region and a dissimilarity average value obtained by averaging dissimilarities of the luminance values of the region, and the second statistic includes at least one of a luminance statistic that is a statistic of time-series data of the luminance average value or a dissimilarity statistic that is a statistic of time-series data of the dissimilarity average value.

According to the first to seventh aspects of the present application, the state of the liquid membrane on the substrate can be quantitatively analyzed by analyzing the liquid membrane state by using a statistical value based on luminance values.

In particular, according to the fifth and sixth aspects of the present application, the switching completion time of the state of the liquid membrane on the substrate can be analyzed.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a substrate processing apparatus;

FIG. 2 is a longitudinal sectional view of a processing unit;

FIG. 3 is a diagram schematically showing how a camera captures an image;

FIG. 4 is a block diagram showing connection between a controller and each constituent element in a processing unit;

FIG. 5 is a flowchart showing a flow of a process of cleaning a substrate;

FIG. 6 is a functional block diagram of the controller;

FIG. 7 is a flowchart showing a flow of a process of acquiring a standard trend;

FIG. 8 is an image view showing an example of a frame image included in moving image data;

FIG. 9 is an image view showing an example of an ROI set in a frame image included in moving image data;

FIG. 10 is a flowchart showing a flow of a process of analyzing and evaluating a liquid membrane state; and

FIG. 11 is a graph showing a luminance average value, a dissimilarity average value, a dissimilarity moving average differential value, and a moving average of these.

### DESCRIPTION OF THE PREFERRED EMBODIMENTS

Hereinafter, an embodiment of the present invention will be described in detail with reference to the drawings.

### 1. Overall Configuration of Substrate Processing Apparatus

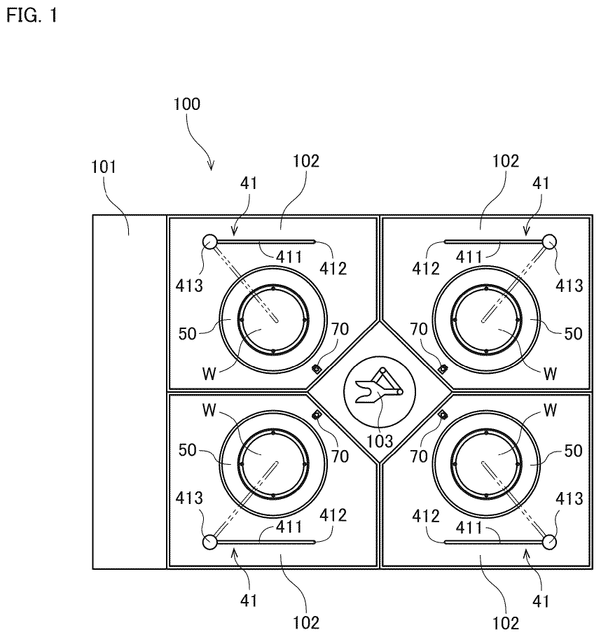

FIG. 1 is a plan view of a substrate processing apparatus 100 as an example of a manufacturing apparatus according to the present invention. The substrate processing apparatus 100 is an apparatus for processing surfaces of disk-like substrates W by supplying a processing liquid to the surfaces of the substrates W during the process of manufacturing the semiconductor wafers. The substrate W of the present embodiment is a silicon wafer. As shown in FIG. 1, the substrate processing apparatus 100 includes an indexer 101, a plurality of processing units 102, and a main transport robot 103.

The indexer 101 is a part for transporting unprocessed substrates W into the apparatus from the outside and transporting processed substrates W to the outside of the apparatus. The indexer 101 includes a plurality of carriers arranged therein, each carrier housing a plurality of substrates W therein. The indexer 101 also includes a transfer robot which is not shown. The transfer robot transfers substrates W between the carriers in the indexer 101 and either the processing units 102 or the main transport robot 103.

Each processing unit 102 is a so-called sheet-fed processing part for processing substrates W one by one. The processing units 102 are arranged around the main transport robot 103. In the present embodiment, three layers of processing units 102 are stacked one above another in a height direction, each layer including four processing units 102 arranged around the main transport robot 103. That is, the substrate processing apparatus 100 according to the present embodiment includes 12 processing units 102 in total. Each processing unit 102 processes a plurality of substrates W in parallel. It is, however, noted that the number of processing units 102 included in the substrate processing apparatus 100 is not limited to 12, and may be any number such as 1, 4, 8, or 24.

The main transport robot 103 is a mechanism for transporting substrates W between the indexer 101 and the processing units 102. For example, the main transport robot 103 may include a hand for holding a substrate W and an arm for moving the hand. The main transport robot 103 takes unprocessed substrates W out of the indexer 101 and transfers these substrates W to the processing units 102. When the processing units 102 have completed the processing of the substrates W, the main transport robot 103 takes the processed substrates W out of the processing units 102 and transfers these substrates W to the indexer 101.

### 2. Configuration of Processing Unit

Next is a description about a detailed configuration of the processing units 102. While the following description is given about one of the processing units 102 included in the substrate processing apparatus 100, the other processing units 102 also have equivalent configurations.

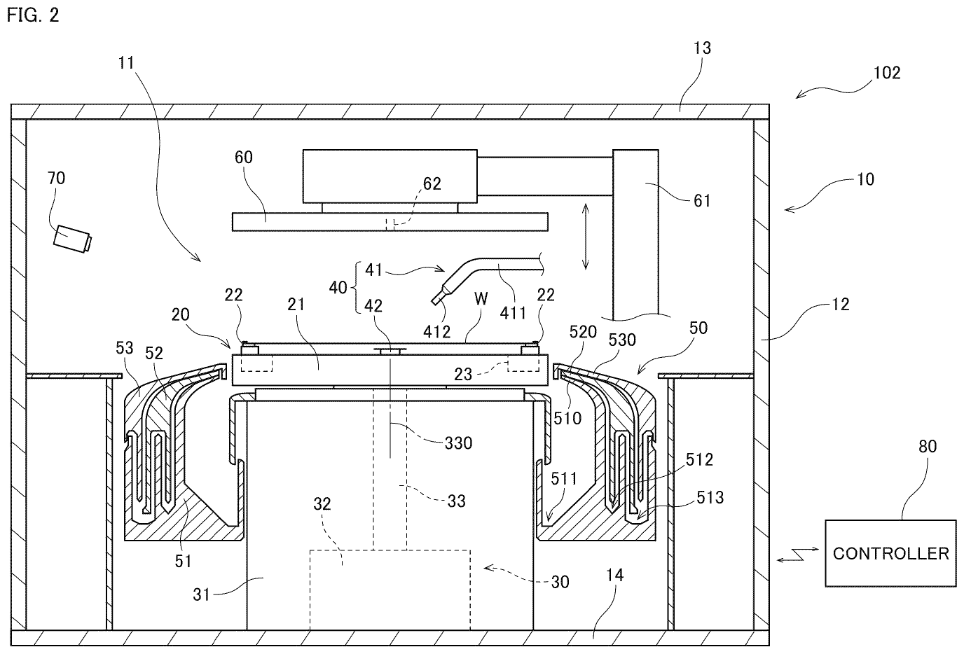

FIG. 2 is a longitudinal sectional view of one processing unit 102. As shown in FIG. 2, the processing unit 102 includes a chamber 10, a substrate holder 20, a rotation mechanism 30, a processing liquid supplier 40, a processing liquid collector 50, a barrier plate 60, a camera 70, and a controller 80.

The chamber 10 is a casing that has a processing space 11 for processing substrates W. The chamber 10 has a side wall 12 that surrounds the sides of the processing space 11, a top plate 13 that covers the top of the processing space 11, and a bottom plate 14 that covers the bottom of the processing space 11. The substrate holder 20, the rotation mechanism 30, the processing liquid supplier 40, the processing liquid collector 50, the barrier plate 60, and the camera 70 are housed in the chamber 10. The side wall 12 is provided with a transport entrance and a shutter, the transport entrance being an entrance for transporting substrates W into and out of the chamber 10, the shutter being a mechanism for opening and closing the transport entrance.

The substrate holder 20 is a mechanism for horizontally holding the substrate W inside the chamber 10. That is, the substrate holder 20 holds the substrate W in such a posture that a normal line of the substrate W is oriented in a vertical direction. As shown in FIG. 2, the substrate holder 20 includes a disk-like spin base 21 and a plurality of chuck pins 22.

The chuck pins 22 are provided at equiangular intervals along the outer periphery of the upper surface of the spin base 21. The substrate W is held by the chuck pins 22 so that the surface to be processed where a pattern is formed faces upward. Each chuck pin 22 comes in contact with the lower surface of the edge portion of the substrate W and with the outer peripheral end face of the substrate W and supports the substrate W at a position above the upper surface of the spin base 21 with a slight gap therebetween.

The spin base 21 includes a chuck-pin switching mechanism 23 for switching the positions of the chuck pins 22. The chuck-pin switching mechanism 23 switches the chuck pins 22 between a holding position at which the chuck pins 22 hold the substrate W and a release position at which the chuck pins 22 release the hold of the substrate W.

The rotation mechanism 30 is a mechanism for rotating the substrate holder 20. The rotation mechanism 30 is housed in a motor cover 31 provided below the spin base 21. As indicated by broken lines in FIG. 2, the rotation mechanism 30 includes a spin motor 32 and a support shaft 33. The support shaft 33 extends in the vertical direction and has its lower end connected to the spin motor 32 and its upper end fixed to the center of the lower surface of the spin base 21. When the spin motor 32 is driven, the support shaft 33 rotates about the shaft center 330. Together with the support shaft 33, the substrate holder 20 and the substrate W held by the substrate holder 20 also rotate about the shaft center 330.

The processing liquid supplier 40 is a mechanism for supplying a processing liquid to an upper surface and a lower surface of the substrate W held by the substrate holder 20. The processing liquid supplier 40 includes a top nozzle 41 and a bottom nozzle 42.

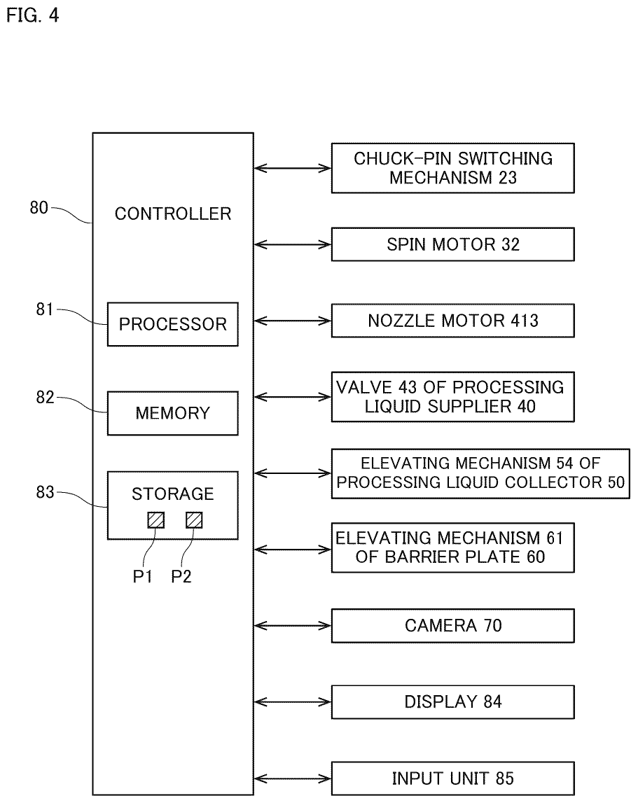

As shown in FIGS. 1 and 2, the top nozzle 41 includes a nozzle arm 411, a nozzle head 412 provided at a tip of the nozzle arm 411, and a nozzle motor 413 (see, FIG. 4). The nozzle arm 411 is driven by the nozzle motor 413 so as to move angularly in the horizontal direction about the root end of the nozzle arm 411. As a result, the nozzle head 412 can be moved between a processing position above the substrate W held by the substrate holder 20 and a retracted position outside the processing liquid collector 50. In FIG. 1, the nozzle arm 411 and the nozzle head 412 arranged at the processing position are indicated by solid lines, and the nozzle arm 411 and the nozzle head 412 arranged at the retracted position are indicated by two-dot chain lines.

The nozzle head 412 is connected to a liquid supplier (not shown) for supplying a processing liquid. As the processing liquid, for example, an SPM cleaning liquid, an SC-1 cleaning liquid, an SC-2 cleaning liquid, a DHF cleaning liquid (dilute hydrofluoric acid), pure water (deionized water, DIW), isopropyl alcohol (IPA), or the like is used. The SPM cleaning liquid is a mixed solution of sulfuric acid and hydrogen peroxide water. The SC-1 cleaning liquid is a mixed solution of aqueous ammonia, hydrogen peroxide water, and pure water. The SC-2 cleaning liquid is a mixed solution of hydrochloric acid, hydrogen peroxide water, and pure water.

When a valve 43 (see, FIG. 4) of the liquid supplier is opened with the nozzle head 412 placed at the processing position, the processing liquid supplied from the liquid supplier is ejected from the nozzle head 412 toward the upper surface of the substrate W held by the substrate holder 20. Note that the nozzle head 412 may be a so-called two-fluid nozzle that mixes the processing liquid with a pressurized gas to generate droplets and ejects a resultant mixed fluid of the droplets and the pressurized gas to the substrate W. As another alternative, each processing unit 102 may include a plurality of top nozzles 41.

The bottom nozzle 42 is arranged inward of a through hole provided in the center of the spin base 21. The bottom nozzle 42 has an ejection outlet that faces the lower surface of the substrate W held by the substrate holder 20. The bottom nozzle 42 is also connected to the liquid supplier for supplying the processing liquid. When the processing liquid is supplied from the liquid supplier to the bottom nozzle 42, the bottom nozzle 42 ejects the processing liquid toward the lower surface of the substrate W.

The processing liquid collector 50 is a part for collecting the used processing liquid. As shown in FIG. 2, the processing liquid collector 50 includes an inner cup 51, an intermediate cup 52, and an outer cup 53. The inner cup 51, the intermediate cup 52, and the outer cup 53 are movable up and down independently of one another by an elevating mechanism 54 (see, FIG. 4).

The inner cup 51 includes a tubular-shaped first guide plate 510 that surrounds a periphery of the substrate holder 20. An upper portion of the first guide plate 510 is tapered toward an upper end. The intermediate cup 52 includes a tubular-shaped second guide plate 520 that surrounds the periphery of the substrate holder 20. An upper portion of the second guide plate 520 is tapered toward an upper end. The second guide plate 520 is located outside and above the first guide plate 510. The outer cup 53 includes a tubular-shaped third guide plate 530 that surrounds the periphery of the substrate holder 20. An upper portion of the third guide plate 530 is tapered toward an upper end. The third guide plate 530 is located outside and above the second guide plate 520.

The bottom of the inner cup 51 extends to below the bottoms of the intermediate cup 52 and the outer cup 53. The upper surfaces of these bottoms are provided with a first drain groove 511, a second drain groove 512, and a third drain groove 513 in order from the inner side.

The processing liquid ejected from the top and bottom nozzles 41 and 42 of the processing liquid supplier 40 is supplied to the substrate W and scattered to the outside by centrifugal force caused by rotation of the substrate W. The processing liquid scattered from the substrate W is collected by one of the first guide plate 510, the second guide plate 520, and the third guide plate 530.

In a case of collecting the processing liquid by the first guide plate 510, all the cups of the inner cup 51, the intermediate cup 52, and the outer cup 53 are arranged at a collection position where the upper ends of the cups are located above the substrate W. In this case, the processing liquid scattered outward from the substrate W is collected by the first guide plate 510, passes through the first drain groove 511, and is discharged to the outside of the processing unit 102.

In a case of collecting the processing liquid by the second guide plate 520, the inner cup 51 is arranged at a standby position (position shown in FIG. 2) on a lower side from the substrate W, and the intermediate cup 52 and the outer cup 53 are arranged at the collection position. In this case, the processing liquid scattered outward from the substrate W is collected by the second guide plate 520, passes through the second drain groove 512, and is discharged to the outside of the processing unit 102.

In a case of collecting the processing liquid by the third guide plate 530, the inner cup 51 and the intermediate cup 52 are arranged at the standby position, and the outer cup 53 is arranged at the collection position. In this case, the processing liquid scattered outward from the substrate W is collected by the third guide plate 530, passes through the third drain groove 513, and is discharged to the outside of the processing unit 102.

In this way, the processing unit 102 includes a plurality of passages for discharging processing liquids. Thus, the processing unit 102 is capable of sorting and collecting processing liquids supplied to the substrate W for each type. Accordingly, collected processing liquids can also be separately disposed of or regenerated depending on the properties of each processing liquid.

The barrier plate 60 is a member for suppressing diffusion of a gas in the vicinity of the surface of the substrate W during certain processing such as dry processing. The barrier plate 60 has a disk-like outside shape and is arranged horizontally above the substrate holder 20. As shown in FIG. 2, the barrier plate 60 is connected to an elevating mechanism 61. When the elevating mechanism 61 is operated, the barrier plate 60 moves up and down between an upper position at which the barrier plate 60 is spaced above from the upper surface of the substrate W held by the substrate holder 20 and a lower position at which the barrier plate 60 is closer to the upper surface of the substrate W than when being at the upper position. In FIG. 2, the barrier plate 60 is arranged at the upper position. For example, the elevating mechanism 61 may be a mechanism for converting rotational motion of a motor into translatory motion by means of a ball screw.

At a center of a lower surface of the barrier plate 60, an air outlet 62 through which a drying gas is blown out is provided. Hereinafter, the gas ejected from the air outlet 62 is referred to as “drying gas”. The air outlet 62 is connected to a gas supplier (not shown) that supplies the drying gas. The drying gas may, for example, be a heated nitrogen gas.

When the processing liquid is supplied from the top nozzle 41 to the substrate W, the barrier plate 60 retracts to the upper position. When dry processing is performed on the substrate W after the supply of the processing liquid, the elevating mechanism 61 moves the barrier plate 60 down to the lower position. Then, the drying gas is issued from the air outlet 62 toward the upper surface of substrate W. At this time, the barrier plate 60 prevents the diffusion of the gas. As a result, the drying gas is efficiently supplied to the upper surface of the substrate W.

The camera 70 is a device that captures an image of a specific operation performed in the chamber 10. For example, the camera 70 may be installed in a position that is in close proximity to the inner surface of the side wall 12 of the chamber 10. The camera 70 is a high-speed frame-based camera. Therefore, moving image data (video image) output by the camera 70 is obtained by arranging, in time series, frame images having information on luminance values of a large number of pixels. The camera 70 transmits moving image data E obtained by image capture to the controller 80.

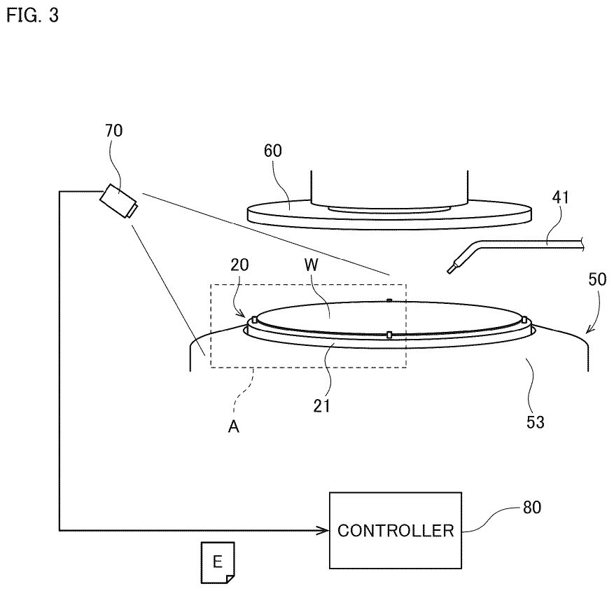

FIG. 3 is a diagram schematically showing how the camera 70 captures an image. In the present embodiment, an observation target region including an end of the substrate W in the upper surface of the substrate W supported by the spin base 21 is set to be included in an image capture region A of the camera 70. In the operation of ejecting the processing liquid from the nozzle head 412 to the surface of the substrate W or in the operation of drying the substrate W, the camera 70 captures an image of this operation performed within the image capture region A. In the example of FIG. 3, the image capture region A does not include the entire upper surface of the substrate W, but the image capture region A may be set such that the image capture region A includes the entire upper surface of the substrate W.

The controller 80 is a unit for controlling operations of each constituent element of the processing unit 102. FIG. 4 is a block diagram showing electrical connection between the controller 80 and each constituent element of the processing unit 102. As schematically shown in FIG. 4, the controller 80 is configured as a computer that includes a processor 81 such as a CPU, memory 82 such as RAM, and a storage 83 such as a hard disk drive.

The storage 83 internally stores an operation control program P1 and a liquid membrane state analysis program P2. The operation control program P1 is a computer program for controlling operations of each constituent element of the processing unit 102 in order to allow the processing unit 102 to perform processing on the substrate W. The liquid membrane state analysis program P2 is a computer program for analyzing and evaluating a liquid membrane state on the substrate W based on the moving image data E obtained from the camera 70.

As shown in FIG. 4, the controller 80 is communicably connected via a cable or wirelessly to each of the aforementioned constituent elements including the chuck-pin switching mechanism 23, the spin motor 32, the nozzle motor 413, the valve 43 of the processing liquid supplier 40, the elevating mechanism 54 of the processing liquid collector 50, the elevating mechanism 61 of the barrier plate 60, and the camera 70. The controller 80 is also electrically connected to a display 84 such as a liquid crystal display and an input unit 85. The controller 80 controls the operations of each constituent element described above based on the operation control program P1 and the liquid membrane state analysis program P2 stored in the storage 83.

### 3. Operations of Substrate Processing Apparatus

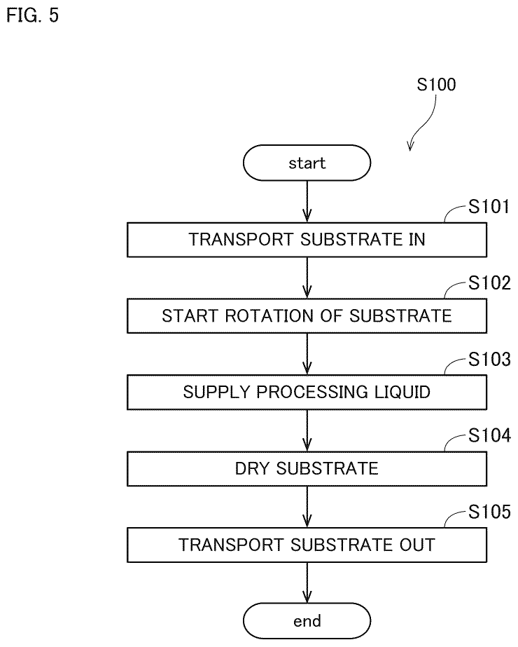

Next is a description of the processing performed on the substrate W in the processing unit 102 described above. FIG. 5 is a flowchart showing a flow of a process of cleaning the substrate W (step S100). The process of cleaning (S100) is implemented by the processor 81 operating according to the operation control program P1 stored in the storage 83.

In the case of processing the substrate W in the processing unit 102, firstly, the main transport robot 103 transports the substrate W to be processed into the chamber 10 (step S101). The substrate W transported into the chamber 10 is horizontally held by the chuck pins 22 of the substrate holder 20. Thereafter, the spin motor 32 of the rotation mechanism 30 is driven so as to start rotation of the substrate W (step S102). Specifically, the support shaft 33, the spin base 21, the chuck pins 22, and the substrate W held by the chuck pins 22 rotate about the shaft center 330 of the support shaft 33.

Then, a processing liquid is supplied from the processing liquid supplier 40 (step S103). In step S103, the nozzle motor 413 is driven so as to move the nozzle head 412 to the processing position facing the upper surface of the substrate W. Then, the processing liquid is ejected from the nozzle head 412 arranged at the processing position, toward a center of the upper surface of the substrate W. The storage 83 in the controller 80 stores parameters such as an ejection rate and an ejection time of the processing liquid in advance. In accordance with these settings, the controller 80 performs the operation of ejecting the processing liquid from the top nozzle 41.

In step S103, a plurality of processing liquids are sequentially supplied to the upper surface of the substrate W. When the supplied processing liquid is switched, the supply of the processing liquid to be supplied next is started before the supply of the previously supplied processing liquid is completed. That is, when the supplied processing liquid is switched, two kinds of processing liquids are temporarily and simultaneously supplied. In step S103, the top nozzle 41 may swing in the horizontal direction at the processing position while ejecting the processing liquid. The processing liquid may also be ejected from the bottom nozzle 42 as necessary.

During the process of supplying the processing liquid in step S103, the barrier plate 60 is placed at the upper position above the top nozzle 41. When the supply of the processing liquid to the substrate W is completed and the top nozzle 41 is placed at the retracted position, the controller 80 operates the elevating mechanism 61 so as to move the barrier plate 60 from the upper position to the lower position. Then, the number of revolutions of the spin motor 32 is increased to enhance the speed of rotation of the substrate W, and the drying gas is issued toward the substrate W from the air outlet 62 provided in the lower surface of the barrier plate 60. In this way, the surface of the substrate W is dried (step S104).

When the dry processing of the substrate W is completed, the spin motor 32 is stopped to stop the rotation of the substrate W. Then, the chuck pins 22 release the hold of the substrate W. Thereafter, the main transport robot 103 takes the processed substrate W out of the substrate holder 20 and transports this substrate W to the outside of the chamber 10 (step S105).

Each processing unit 102 performs the above-described processing in steps S101 to S105 repeatedly on a plurality of substrates W that are transported in sequence.

### 4. Analysis and Evaluation of Liquid Membrane State

Next, analysis and evaluation of a liquid membrane state of the substrate W in the substrate processing apparatus 100 will be described. Hereinafter, the description is given following a process of acquiring a standard trend (S200) performed prior to the process of analyzing and evaluating, and the process of analyzing and evaluating the liquid membrane state (S300) in the process of supplying the processing liquid (S103).

the process of acquiring the standard trend (S200) and the process of analyzing and evaluating the liquid membrane state (S300) are implemented by the processor 81 operating according to the liquid membrane state analysis program P2 stored in the storage 83.

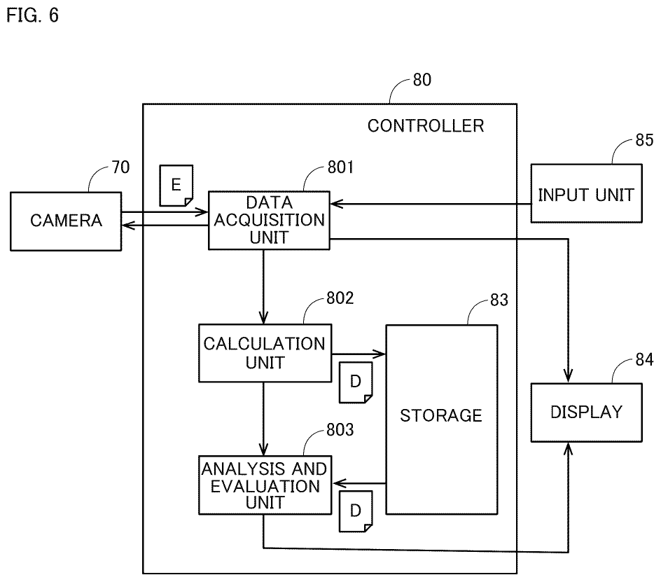

FIG. 6 is a functional block diagram of the controller 80. As illustrated in FIG. 6, the controller 80 includes a data acquisition unit 801, a calculation unit 802, and an analysis and evaluation unit 803 as functional units based on the liquid membrane state analysis program P2.

The data acquisition unit 801 acquires the moving image data E obtained by capturing an image of a liquid membrane on the upper surface of the substrate W from the camera 70, and displays the moving image data E on the display 84. In addition, the data acquisition unit 801 acquires a range of region of interest (ROI) in the moving image data E from the input unit 85. The calculation unit 802 calculates luminance, a dissimilarity, a statistic of the luminance, and a statistic of the dissimilarity of the ROI for each frame image F of the moving image data E. The analysis and evaluation unit 803 analyzes and evaluates the state of the liquid membrane on the upper surface of the substrate W based on each value calculated by the calculation unit 802.

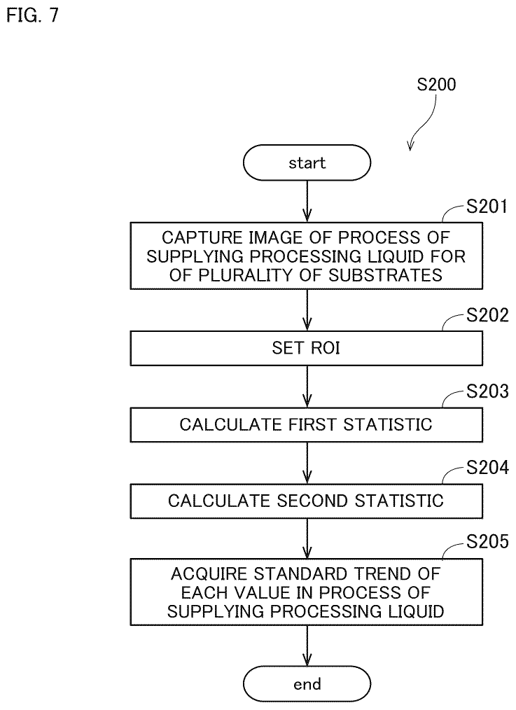

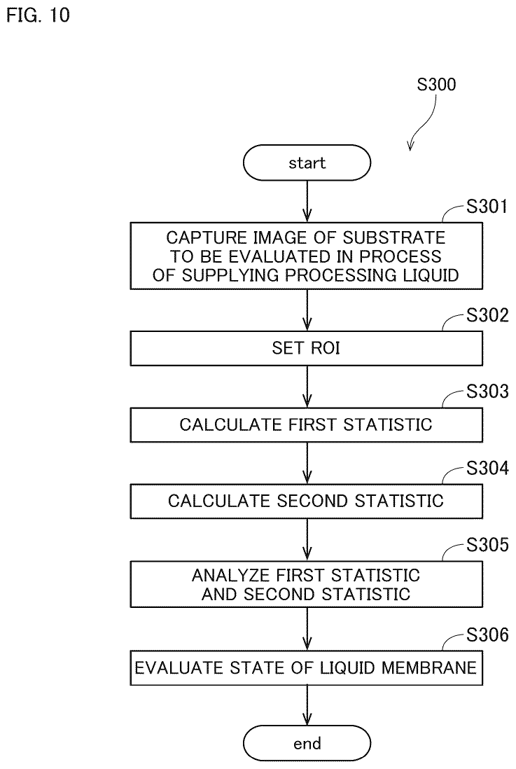

FIG. 7 is a flowchart showing a flow of the process of acquiring the standard trend (step S200). The process of acquiring the standard trend shown in FIG. 7 is performed prior to the process of analyzing and evaluating the liquid membrane state shown in FIG. 10.

In the process of acquiring the standard trend (S200), first, the data acquisition unit 801 captures an image of the process of supplying the processing liquid (S103) with the camera 70 for a plurality of substrates W for the processing unit 102 to be evaluated (step S201). The camera 70 transmits the obtained moving image data E to the controller 80. As a result, the data acquisition unit 801 acquires a plurality of pieces of the moving image data E.

Subsequently, the data acquisition unit 801 displays the acquired moving image data E on the display 84. Then, the user sets a region of interest (ROI) in the input unit 85 for the moving image data E displayed on the display 84, and inputs the ROI to the data acquisition unit 801 (step S202). In step S202, the ROI may be set for each of all pieces of the moving image data E, or a common ROI may be set for the plurality of pieces of moving image data E.

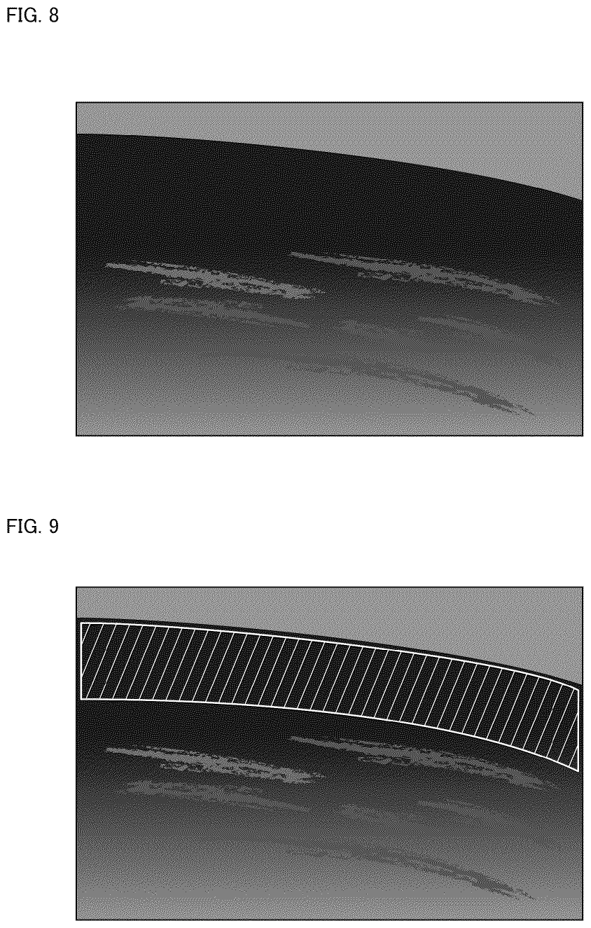

FIG. 8 is an image view showing an example of a plurality of frame images F included in the moving image data E. In the frame image F of FIG. 8, an image of a part of the upper surface of the substrate W including the end of the disk-like substrate W is captured. FIG. 9 is an image view showing the ROI set in the frame image F of FIG. 8. In FIG. 9, the ROI is indicated by a white frame and a white diagonal line. In FIG. 9, a region near the end of the substrate W is set as the ROI.

Next, the calculation unit 802 acquires luminance values of individual pixels of the ROI for each of the frame images F included in the moving image data E, and calculates a first statistic (step S203). The first statistic is a luminance average value obtained by averaging luminance values of the entire ROI and a dissimilarity average value obtained by averaging dissimilarities of luminance values of the entire ROI. One luminance average value and one dissimilarity average value are calculated for each frame image F. Therefore, each of the luminance average value and the dissimilarity average value is one piece of time-series data for one piece of the moving image data E.

Specifically, the dissimilarity of the luminance value is calculated from the luminance value of an n×n region centered on each pixel of the ROI. The n×n region is, for example, 3×3 or 5×5. For the dissimilarity, for example, a gray-level co-occurrence matrix (GLCM) is calculated to normalize the image, and then the dissimilarity is calculated for each pixel of the ROI. The dissimilarity average value is calculated by averaging the dissimilarities of the entire ROI calculated in this manner.

Thereafter, the calculation unit 802 calculates at least one second statistic on the basis of time-series data of the first statistics of the moving image data E (step S204). The second statistic includes at least one of a luminance statistic that is a statistic of the luminance average value of the ROI and a dissimilarity statistic that is a statistic of the dissimilarity average value of the ROI.

The luminance statistic includes, for example, a luminance moving average that is a moving average of the luminance average values for each period of a predetermined length, and a luminance standard deviation that is a standard deviation of the luminance average values for each period of a predetermined length. In addition, the dissimilarity statistic includes, for example, a dissimilarity moving average which is a moving average of the dissimilarity average values for each period of a predetermined length, a dissimilarity standard deviation which is a standard deviation of the dissimilarity average values for each period of a predetermined length, a dissimilarity moving average differential value which is a first order differential of the dissimilarity moving average, and a moving average of the dissimilarity moving average differential value. Note that the period of the predetermined length is, for example, 40 frames.

The calculation unit 802 stores the first statistic and the second statistic acquired and calculated in steps S203 and S204 in the storage 83, as a standard trend D of each value (step S205). Note that the moving image data E input in step S201 to obtain the standard trend D is preferably the moving image data E of the substrate W for which the process of cleaning and drying is determined to be appropriate as a result. In this way, in subsequent step S300, the moving image data E to be analyzed is compared with the standard trend D of non-defective products alone, and accuracy of the analysis and evaluation as to whether or not the processing of the substrate W whose image is captured in the moving image data E to be analyzed is appropriate is improved.

FIG. 10 is a flowchart showing a flow of the process of analyzing and evaluating the liquid membrane state (step S300). In the process of analyzing and evaluating the liquid membrane state (step S300), first, the data acquisition unit 801 captures an image of the substrate W to be evaluated in the process of supplying the processing liquid (S103), with the camera 70 (step S301). The camera 70 transmits the obtained moving image data E to the controller 80. As a result, the data acquisition unit 801 acquires a plurality of pieces of the moving image data E.

Subsequently, the data acquisition unit 801 displays the acquired moving image data E on the display 84. Then, the user sets a region of interest (ROI) in the input unit 85 for the moving image data E displayed on the display 84, and inputs the ROI to the data acquisition unit 801 (step S302). In a case where a common ROI is set to the plurality of pieces of moving image data E in step S202 of the process of acquiring the standard trend (S200), the same ROI may be used in step S302.

Next, the calculation unit 802 acquires luminance values of individual pixels of the ROI for each of the frame images F included in the moving image data E, and calculates a luminance average value and a dissimilarity average value which are a first statistic (step S303). Thereafter, similarly to step S204, the calculation unit 802 calculates at least one of a luminance statistic or a dissimilarity statistic as a second statistic for each piece of the moving image data E (step S304).

The calculation unit 802 analyzes the first statistic and the second statistic acquired and calculated in steps S303 and S304 (step S305). Specifically, each value stored in the storage 83 is compared with the standard trend D, or whether or not each value is within a standard range is analyzed using a threshold calculated on the basis of the standard trend D. Then, the calculation unit 802 evaluates whether or not the state of the liquid membrane on the substrate W is appropriate on the basis of the analysis result of step S305 (step S306).

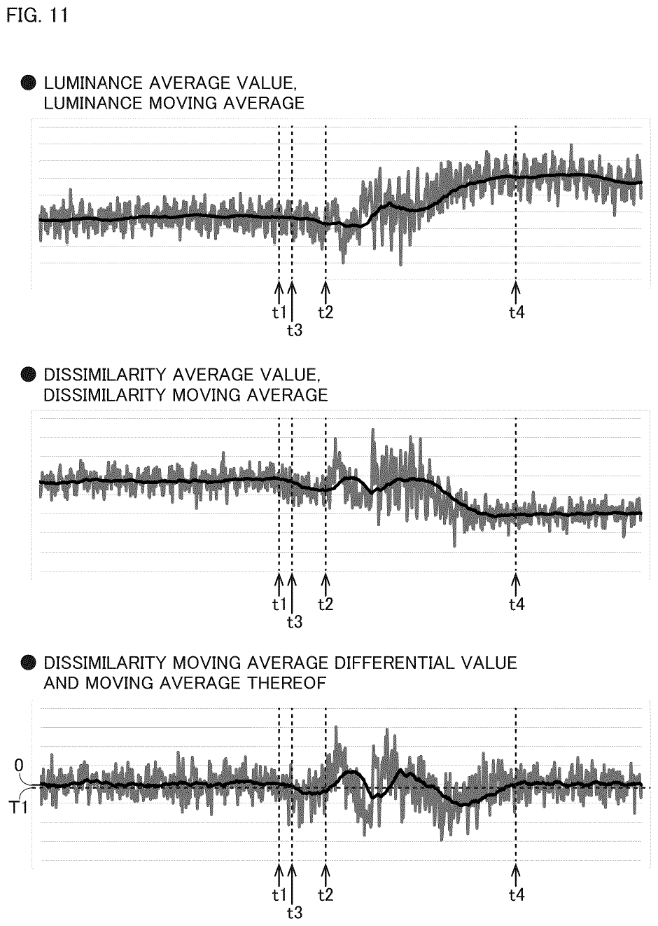

FIG. 11 is a graph showing an example of time-series data of the first statistic and the second statistic acquired and calculated in steps S304 and S305. The upper part of FIG. 11 shows a luminance average value (gray) and a luminance moving average (black) which is a moving average of the luminance average value (gray). The middle part of FIG. 11 shows a dissimilarity average value (gray) and a dissimilarity moving average (black) which is a moving average thereof. The lower part of FIG. 11 shows a dissimilarity moving average differential value (gray) and a moving average thereof (black). FIG. 11 shows individual values in a first state, a transition period of transition of the state of the supply liquid from the first state to a second state, and the subsequent second state, in the process of supplying the processing liquid (S103).

The transition from the first state to the second state is, for example, a change in flow rate, a change in ejection nozzle, a change in ejection liquid, or the like. Therefore, when the flow rate is changed, the transition period is a period from a start to an end of the change of the flow rate. Further, in a case of changing the ejection nozzle or changing the ejection liquid involving the ejection nozzle, the first state is a period in which the liquid is ejected from only the first nozzle, the transition period is a period in which the ejection by the second nozzle is started and the ejection is performed from both the first nozzle and the second nozzle, and thereafter, the second state is started when the ejection from the first nozzle is stopped. Then, a time point when the state of a liquid surface becomes stable after the transition period is switched to the second state is referred to as a switching completion time.

In the data of FIG. 11, time t1 is the transition period start time, and time t2 is the transition period end time, that is, the second state start time. That is, a period from the start of the data to time t1 in FIG. 11 is the first state. Time t1 to time t2 is the transition period. After time t2, the state is the second state. In addition, time t4 is the switching completion time at which the state of the liquid surface becomes stable after the transition period is switched to the second state.

The luminance average value is stable in the first state (before time t1), and no significant change is observed during the transition period time (t1 to t2) although the luminance average value slightly decreases. Thereafter, in the second state (after time t2), the luminance average value rises while fluctuating up and down, and after time t4, the luminance average value becomes stable at a value higher than that in the first liquid supply state (before time t1).

Looking at the luminance value moving average which is the moving average of the luminance average value, two downward peaks and one upward peak are observed from time t1 to time t4.

Whereas, the dissimilarity is stable in the first state (before time t1), but decreases in a state where two types of liquids are supplied (from time t1 to time t2). Thereafter, in the second state (after time t2), the dissimilarity falls with fluctuation, and after time t4, the dissimilarity is stable at a value lower than that in the first state (before time t1).

Looking at the dissimilarity moving average, which is the moving average of the dissimilarity, two downward peaks and two upward peaks are observed from time t1 to time t4.

In addition, the dissimilarity moving average differential value, which is the first order differential of the dissimilarity moving average, is stable around 0 in both the first state (before time t1) and after time t4. Whereas, a large fluctuation is observed in the dissimilarity moving average differential value in the transition period (time t1 to t2) and before time t4 in the second state (after time t2).

In particular, the moving average of the dissimilarity moving average differential value does not fall below a negative first threshold T1 indicated by a dotted line, in the first state (before time t1) and after time t4. In addition, when looking at the moving average of the dissimilarity moving average differential value, three downward peaks and two upward peaks are observed from time t1 to time t4.

In the substrate processing apparatus 100 according to the present embodiment, when the transition from the first state to the second state is made, the tendency described above has been observed for the ROI of all the moving image data E for the non-defective substrate W. In the actual moving image data E, it is difficult to match which frame of the moving image data E corresponds to the times t1 and t2, so that the state switching period can be calculated by the following technique.

The moving average of the dissimilarity moving average differential value falls below the first threshold T1 having the negative value at a time closer to time t1 than time t2 after time t1. Therefore, time t3 at which the moving average of the dissimilarity moving average differential value falls below the first threshold T1 is set as a switching start time t3. Note that the first threshold T1 and a second threshold T2 to be described later may simply be stored in the storage 83 in advance.

In addition, the moving average of the dissimilarity moving average differential value becomes 0 or more after three downward peaks after time t3, and then becomes stable near 0. Therefore, after time t3, time t4 at which the second threshold T2=0 is exceeded after a negative peak is shown a predetermined number of times (three times) is set as a switching completion time t4. After time t4 calculated in this manner, both the luminance average value and the dissimilarity maintain stable values, and thus the state of the liquid membrane is considered to be stable.

The state of the liquid membrane on the substrate W can be quantitatively analyzed using such a trend of each calculated value. Then, the liquid membrane state in the same process can be evaluated.

In the case of evaluating the liquid membrane state in the same process, the calculated values are compared between the moving image data E of the substrate W to be analyzed and the standard trend D of only the non-defective product, in the analysis process of step S305. Then, for example, when the peak value of the luminance value moving average or the dissimilarity moving average is greatly different from the standard trend D, it is evaluated that the liquid membrane state is highly likely to be defective in the evaluation process of step S306.

Although not shown in FIG. 11, in the analysis process of step S305, when the luminance standard deviation or the dissimilarity standard deviation greatly differs from the standard trend D, the liquid membrane state is highly likely to be defective in the evaluation process of step S306.

In addition, in a case of changing an amount of a chemical liquid to be supplied or a rotation speed of the substrate W, it is possible to evaluate the liquid membrane state in different processes.

As an example, for example, evaluation by comparison of a state switching time can be performed. In this case, in the analysis process of step S305, time t2 and time t4 are calculated from the moving average of the dissimilarity moving average differential value by using the technique described above, and the period from time t2 to time t4 is calculated as the state switching time. Then, in a case where the calculated state switching time is longer than the standard trend D representing the conventional process, it is evaluated that switching of the liquid is not smooth in the evaluation process of step S306. Whereas, when the calculated state switching time is shorter than the standard trend D, it is evaluated that the switching from the first state to the second state is smooth in the evaluation process of step S306.

Furthermore, as another example, for example, evaluation by comparison of each statistic within the state switching time can be performed. In this case, in the analysis process of step S305, when the standard deviation of the luminance value and the standard deviation of the dissimilarity are obviously larger than the standard deviation in the standard trend D, it may be evaluated that the substrate W may have been exposed at the time of switching from the first state to the second state.

### 5. Variations

While one embodiment of the present invention has been described thus far, the present invention is not intended to be limited to the above-described embodiment.

In the above-described embodiment, regarding the movement of the values used for analysis and evaluation, a value of the individual values has been described regarding switching from the specific first state to second state, but the present invention is not limited thereto. The switching from the first state to the second state may be switching of any state such as a change in flow rate, a change in ejection nozzle, or a change in ejection liquid. In that case, behaviors of individual values are different from those described above. Therefore, the liquid membrane state can be appropriately analyzed and evaluated by grasping a typical behavior of each value by the process of acquiring the standard trend (S200) and then performing the process of analyzing and evaluating the liquid membrane state (S300).

In the above-described embodiment, an image of a specific operation is captured in one of the plurality of processing units 102, and the state of the liquid membrane of the supply liquid for each substrate W is analyzed and evaluated. However, in the plurality of processing units 102, an image of the same liquid supply processing may be captured a plurality of times, and the standard trend D may be acquired on the basis of the obtained moving image data E and used for evaluation.

In addition, the individual elements appearing in the above-described embodiment and variations may be appropriately combined as long as no contradiction occurs.

While the invention has been shown and described in detail, the foregoing description is in all aspects illustrative and not restrictive. It is therefore understood that numerous modifications and variations can be devised without departing from the scope of the invention.

What is claimed is:

1. An analysis method for analyzing a state of a liquid membrane on a substrate, the liquid membrane being of a liquid supplied to the substrate that is rotating in a substrate processing apparatus, the analysis method comprising:
a) acquiring luminance values of individual pixels in a region that is predetermined, from a video image obtained by imaging a surface of the substrate, and calculating a first statistic from the luminance values;
b) calculating a second statistic that is a statistic of time-series data of the first statistic; and
c) analyzing a state of the liquid membrane on the substrate based on at least one of the first statistic or the second statistic,
wherein
the first statistic includes:
a luminance average value obtained by averaging the luminance values of the region; and
a dissimilarity average value obtained by averaging dissimilarities of the luminance values of the region, and
the second statistic includes at least one of:
a luminance statistic that is a statistic of time-series data of the luminance average value; or
a dissimilarity statistic that is a statistic of time-series data of the dissimilarity average value.

2. The analysis method according to claim 1, wherein
the luminance statistic includes
a luminance standard deviation value that is a standard deviation of the luminance average values for each period of a predetermined length.

3. The analysis method according to claim 1, wherein
the dissimilarity statistic includes:
a dissimilarity standard deviation that is a standard deviation of the dissimilarity average values for each period of a predetermined length.

4. The analysis method according to claim 1, wherein
the dissimilarity statistic includes:
a dissimilarity moving average differential value that is a first order differential of the dissimilarity moving average.

5. The analysis method according to claim 1, wherein
the dissimilarity statistic includes:
a dissimilarity moving average differential value that is a first order differential of the dissimilarity moving average,
in the process of a), the video image is obtained by capturing an image of a first state, a transition period of transition from the first state to a second state, and the second state, and
in the process of c), a switching completion time at which the liquid membrane on the substrate has become stable in the second state is analyzed based on the dissimilarity moving average differential value.

6. The analysis method according to claim 5, wherein
the dissimilarity statistic includes:
a dissimilarity moving average differential value that is a first order differential of the dissimilarity moving average; and
a moving average of the dissimilarity moving average differential value, and in the process of c),
a time, at which a moving average of the dissimilarity moving average differential value falls below a first threshold that is a predetermined negative value, is set as a start time of the transition period, and
a time, at which a moving average of the dissimilarity moving average differential value exceeds a second threshold after showing a negative peak a predetermined number of times, is set as the switching completion time.

7. An evaluation method for analyzing and evaluating a state of a liquid membrane on a substrate, the liquid membrane being of a liquid supplied to the substrate that is rotating in a substrate processing apparatus, the evaluation method comprising:
p) acquiring luminance values of individual pixels from a predetermined region of a video image obtained by imaging a surface of each of a plurality of the substrates when an identical process is performed on the substrates, and calculating a first statistic from the luminance values;
q) calculating a second statistic that is a statistic of time-series data of the first statistic; and
r) analyzing and evaluating a state of the liquid membrane on the substrate based on at least one of the first statistic or the second statistic,
wherein
the first statistic includes:
a luminance average value obtained by averaging the luminance values of the region; and
a dissimilarity average value obtained by averaging dissimilarities of the luminance values of the region, and
the second statistic includes at least one of:
a luminance statistic that is a statistic of time-series data of the luminance average value; or
a dissimilarity statistic that is a statistic of time-series data of the dissimilarity average value.
